(19) United States
(12) Patent Application Publication
(10) Pub. No.: US 2005/0118770 A1
(43) Pub. Date: Jun. 2, 2005

(54) Method for introducing hydrogen into a channel region of a metal oxide semiconductor (MOS) device

(75) Inventors: Mahalingam Nandakumar, Richardson, TX (US); Shaoping Tang, Plano, TX (US); Haowen Bu, Plano, TX (US)

Correspondence Address: TEXAS INSTRUMENTS INCORPORATED, P O BOX 655474, M/S 3999, DALLAS, TX, 75265, US

(73) Assignee: Texas Instruments, Inc., Dallas, TX (US)

(21) Appl. No.: 10/956,864

(22) Filed: Oct. 1, 2004

Related U.S. Application Data
(60) Provisional application No. 60/507,678, filed on Oct. 1, 2003.

(51) Int. Cl. H01L 29/94

(52) U.S. Cl. 438/305; 438/958; 438/38

(57) ABSTRACT

The present invention provides a method for manufacturing a semiconductor device and a method for manufacturing an integrated circuit including the same. The method for manufacturing the semiconductor device, among other steps, includes forming a gate structure (230) over a substrate (210) and forming at least a portion of source/drain regions in the substrate (210). The method further includes annealing the substrate containing the at least a portion of source/drain regions in the presence of hydrogen, and forming an interlevel dielectric layer over the substrate (210) having previously been annealed in the presence of hydrogen.

### CROSS-REFERENCE TO PROVISIONAL APPLICATION

This application claims the benefit of U.S. Provisional Application No. 60/507,678 entitled “SPIKE ANNEAL IN FORMING AFTER SOURCE-DRAIN OR AFTER NLDD IMPLANTS TO ELIMINATE BORON PILE-UP AT CHANNEL SURFACE AND IMPROVE NMOS LDRIVE,” to Mahalingam Nandakumar, et al., filed on Oct. 1, 2003, which is commonly assigned with the present invention and incorporated herein by reference as if reproduced herein in its entirety.

### TECHNICAL FIELD OF THE INVENTION

The present invention is directed, in general, to a method for manufacturing a semiconductor device and, more specifically, to a method for manufacturing a semiconductor device including annealing a substrate containing at least a portion of source/drain regions in the presence of hydrogen, and a method for manufacturing an integrated circuit including the aforementioned method for manufacturing a semiconductor device.

### BACKGROUND OF THE INVENTION

There exists a continuing need to improve semiconductor device performance and further scale semiconductor devices. A characteristic that limits scalability and device performance is electron and hole mobility, also referred to as channel mobility, throughout the channel region of transistors. As devices continue to shrink in size, the channel region for transistors continues to also shrink in size, which can limit channel mobility.

One technique that may improve scaling limits and device performance is to introduce strain into the channel region, which can improve electron and hole mobility. Different types of strain, including expansive strain, uniaxial tensile strain, and compressive strain, have been introduced into channel regions of various types of transistors in order to determine their affect on electron and/or hole mobility. For some devices, certain types of strain improve mobility whereas other types degrade mobility.

Turning briefly to FIG. 1 illustrated is a cross-sectional view of a semiconductor device 100 at a stage of fabrication wherein a tensile stress is introduced by a silicon nitride cap-annealing process, as described in the U.S. patent application Ser. No. 10/662,850, filed on Sep. 15, 2003, by Bu, H. et al. The semiconductor device 100, which happens to be an n-channel metal oxide semiconductor (NMOS) device, includes a substrate 110 having a well region 120 located therein. The semiconductor device 100 of FIG. 1 further includes a gate structure 130 located over the substrate 110. The gate structure 130, as appreciated, includes both a gate dielectric layer 133 and a gate electrode layer 138.

Positioned on both sides of the gate structure 130 are source/drain sidewall spacers 140. The source/drain sidewall spacers 140 illustrated in FIG. 1 each include only a single sidewall spacer. Those skilled in the art understand, however, that various other types of spacers, including offset spacers, L-shaped spacers and others could nevertheless be used. Positioned in the substrate 110 proximate the gate structure 130 are source/drain regions 150. The source/drain regions 150 therefore define a channel region 160 in the substrate 110.

After the source/drain regions 150 have been formed by implanting a suitable dopant, such as arsenic in the instant case, a stress-inducing layer 170 is deposited over the substrate 110 and gate structure 130. Among other processes, a chemical vapor deposition (CVD) process could be used to form the stress-inducing layer 170. Generally, the temperature of the deposition should be lower than the re-crystallization temperature of amorphous silicon. Then, a rapid thermal anneal is performed at a relatively high temperature, introducing and locking stress 180 into the channel region 160. The stress-inducing layer 170 is then removed and silicide regions (not shown) are typically formed on the source/drain regions 150 and gate electrode layer 138. A suitable silicide process is a conventional cobalt, nickel or other similar metal salicide process.

Compressive stress from the gate electrode layer 138 is enhanced by the annealing process described above, which introduces tensile stress 180 across the channel region 170. This tensile stress 180 can improve the performance of the semiconductor device 100 by improving hole and electron mobility in the channel region 160. The cap-annealing process described supra can show improvement for, among others, NMOS devices. Unfortunately, it has been observed that the introduction of stress into the channel region 160, alone, is insufficient to support some of the next generation devices.

Accordingly, what is needed in the art is an improved method for manufacturing a semiconductor device, and a device manufactured using that method, which provides improved channel mobility.

### SUMMARY OF THE INVENTION

To address the above-discussed deficiencies of the prior art, the present invention provides a method for manufacturing a semiconductor device and a method for manufacturing an integrated circuit including the same. The method for manufacturing the semiconductor device, among other steps, includes forming a gate structure over a substrate and forming at least a portion of source/drain regions in the substrate. The method further includes annealing the substrate containing the at least a portion of source/drain regions in the presence of hydrogen, and forming an interlevel dielectric layer over the substrate having previously been annealed in the presence of hydrogen.

The method for manufacturing an integrated circuit, on the other hand, without limitation includes: forming semiconductor devices as mentioned above, and forming interconnects within the interlevel dielectric layer and contacting the semiconductor devices, thereby forming an operational integrated circuit.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

Prior Art FIG. 1 illustrates a cross-sectional view of a semiconductor device at a stage of fabrication wherein a compressive stress is introduced by a conventional cap-annealing process;

FIG. 2 illustrates a cross-sectional view of a partially completed semiconductor device manufactured in accordance with the principles of the present invention;

FIG. 3 illustrates a cross-sectional view of the partially completed semiconductor device illustrated in FIG. 2 after formation of portions of gate sidewall spacers;

FIG. 4 illustrates a cross-sectional view of the partially completed semiconductor device illustrated in FIG. 3 after formation of lightly doped source/drain extension implants within the substrate;

FIG. 5 illustrates a cross-sectional view of the partially completed semiconductor device illustrated in FIG. 4, after annealing the semiconductor device in the presence of hydrogen as referenced with respect to FIG. 4, and after forming additional portions of the gate sidewall spacers;

FIG. 6 illustrates a cross-sectional view of the partially completed semiconductor device illustrated in FIG. 5 after the formation of highly doped source/drain implants within the substrate;

FIG. 7 illustrates a cross-sectional view of the partially completed semiconductor device illustrated in FIG. 6 after forming a composite cap over the substrate in accordance with the principles of the present invention;

FIG. 8 illustrates a cross-sectional view of the partially completed semiconductor device illustrated in FIG. 7 after removing the composite cap;

FIG. 9 illustrates a cross-sectional view of the partially completed semiconductor device illustrated in FIG. 8 after conventionally forming silicided source/drain regions and a silicided gate electrode layer;

FIG. 10 illustrates a cross-sectional view of the partially completed semiconductor device illustrated in FIG. 9 after forming a stress-inducing layer over the gate structure and substrate;

FIG. 11 illustrates a cross-sectional view of the partially completed semiconductor device illustrated in FIG. 10 after subjecting the stress-inducing layer to a thermal anneal to impart a stress into a channel region under the gate structure; and

FIG. 12 illustrates a cross-sectional view of a conventional integrated circuit (IC) incorporating a semiconductor device constructed according to the principles of the present invention.

### DETAILED DESCRIPTION

The present invention is somewhat based on the unique acknowledgment that semiconductor device performance may be dramatically increased by decreasing the dopant pile-up, often boron pile-up, that frequently occurs at the gate dielectric/substrate interface near the channel region of a semiconductor device. Given this acknowledgment, the present invention recognized that the introduction of hydrogen into the channel region causes a significant portion of the piled-up dopants to redistribute and/or leave the channel region of the substrate.

Having acknowledged that the introduction of hydrogen into the channel region of a semiconductor device substantially reduces dopant pile-up at the interface of the gate dielectric and the substrate, the present invention further recognized that the hydrogen could be incorporated into the channel region by annealing the semiconductor device, having already had at least a portion of its source/drain regions formed, in the presence of hydrogen. For example, as the anneal process occurs the hydrogen diffuses into the channel region and some dopants may diffuse out of the channel region, thereby altering the dopant profile of the channel region. As a result, the channel region has somewhat of a retrograde profile wherein the dopant, often p-type dopant, concentration near a surface of the channel region is reduced. Advantageously, the retrograde profile can improve channel mobility for electrons and/or holes through the channel region.

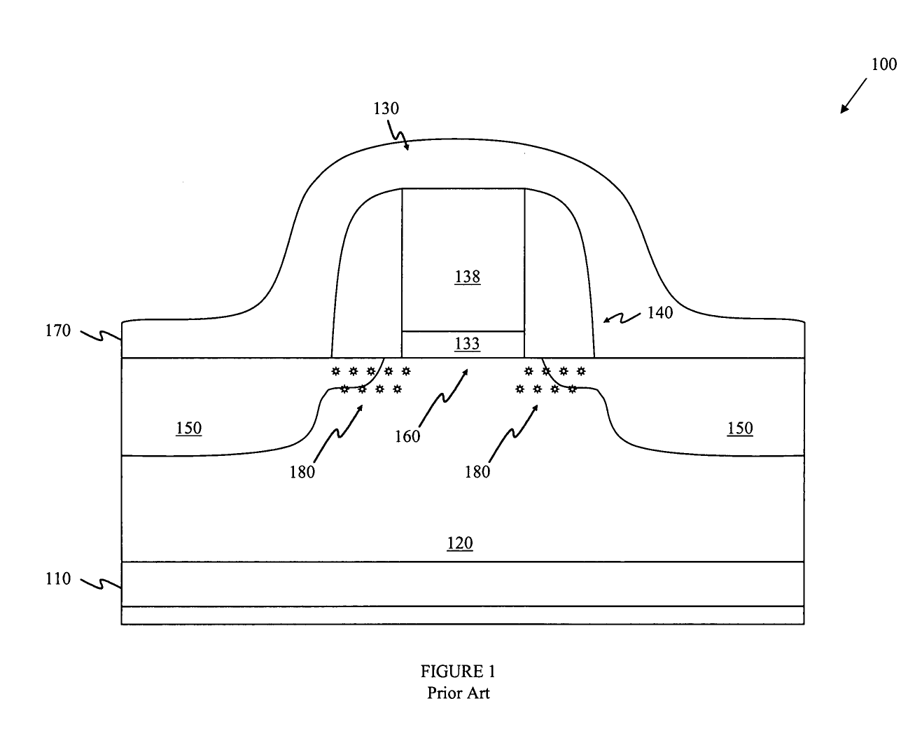

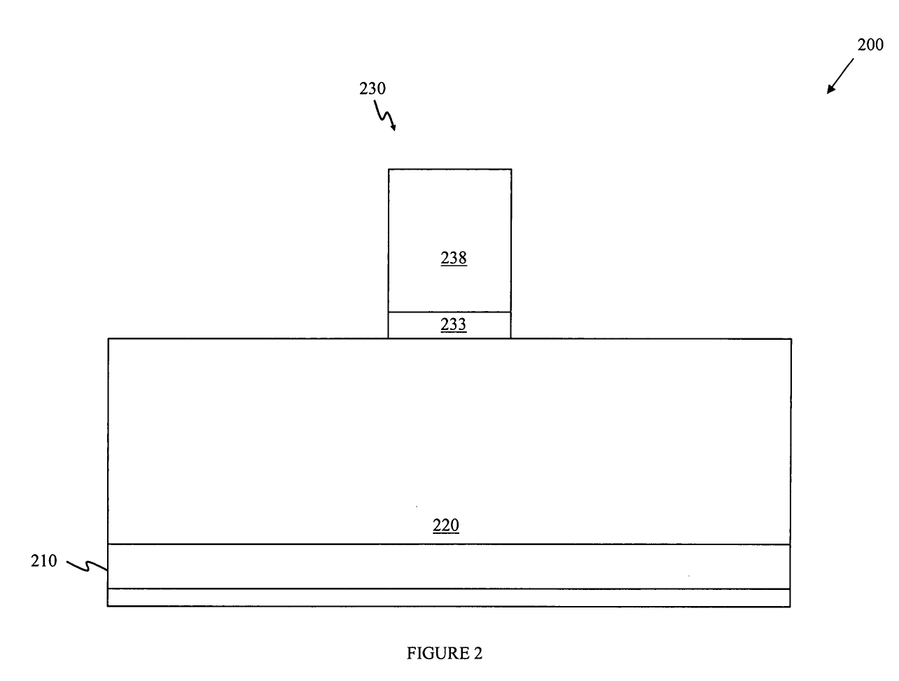

Turning now to FIGS. 2-11, illustrated are cross-sectional views of detailed manufacturing steps illustrating how one might manufacture a semiconductor device in accordance with the principles of the present invention. FIG. 2 illustrates a cross-sectional view of a partially completed semiconductor device 200 manufactured in accordance with the principles of the present invention. From the outset, it should be noted that the embodiment of FIGS. 2-11 will be discussed as an n-channel metal oxide semiconductor (NMOS) device. In an alternative embodiment, all the dopant types, except for possibly the substrate dopant, could be reversed, resulting in a p-channel metal oxide semiconductor (PMOS) device. However, at least with regard to FIGS. 2-11, no further reference to this opposite scheme will be discussed.

In the advantageous embodiment shown, the partially completed semiconductor device 200 of FIG. 2 includes a substrate 210. The substrate 210 may, in an exemplary embodiment, be any layer located in the partially completed semiconductor device 200, including a wafer itself or a layer located above the wafer (e.g., epitaxial layer). In the embodiment illustrated in FIG. 2, the substrate 210 is a P-type substrate; however, one skilled in the art understands that the substrate 210 could more than likely be an N-type substrate without departing from the scope of the present invention.

Located within the substrate 210 in the embodiment shown in FIG. 2 is a well region 220. The well region 220 in the embodiment illustrated in FIG. 2 contains a P-type dopant. For example, the well region 220 would likely be doped with a P-type dopant dose ranging from about 1E13 atoms/cm² to about 1E14 atoms/cm² and at an energy ranging from about 100 keV to about 500 keV. This results in the well region 220 having a peak dopant concentration ranging from about 5E17 atoms/cm³ to about 1E19 atoms/cm³. Those skilled in the art understand that in certain circumstances where the P-type substrate 210 dopant concentration is high enough, the well region 220 may be excluded.

Located over the substrate 210 in the embodiment of FIG. 2 is a gate structure 230. The gate structure 230 includes a gate oxide 233 and a polysilicon gate electrode 238. The gate oxide 233 may comprise a number of different materials and stay within the scope of the present invention. For example, the gate oxide 233 may comprise silicon dioxide, or in an alternative embodiment comprise a high dielectric constant (K) material. In the illustrative embodiment of FIG. 2, however, the gate oxide 233 is a silicon dioxide layer having a thickness ranging from about 0.5 nm to about 5 nm.

Any one of a plurality of manufacturing techniques could be used to form the gate oxide 233. For example, the gate oxide 233 may be either grown or deposited. Additionally, the growth or deposition steps may require a significant number of different temperatures, pressures, gasses, flow rates, etc.

While the advantageous embodiment of FIG. 2 discloses that the polysilicon gate electrode 238 comprises standard polysilicon, other embodiments exist where the polysilicon gate electrode 238, or at least a portion thereof, comprises amorphous polysilicon material, a metal material, or fully silicided metal material. The amorphous polysilicon embodiment may be particularly useful when a substantially planar upper surface of the polysilicon gate electrode 238 is desired.

The deposition conditions for the polysilicon gate electrode 238 may vary, however, if the polysilicon gate electrode 238 were to comprise standard polysilicon, such as the instance in FIG. 2, the polysilicon gate electrode 238 could be deposited using a pressure ranging from about 100 torr to about 300 torr, a temperature ranging from about 620° C. to about 700° C., and a SiH₄ or Si₂H₆ gas flow ranging from about 50 sccm to about 150 sccm. If, however, amorphous polysilicon were desired, the amorphous polysilicon gate electrode could be deposited using a pressure ranging from about 100 torr to about 300 torr, a temperature ranging from about 450° C. to about 550° C., and a SiH₄ or Si₂H₆ gas flow ranging from about 100 sccm to about 300 sccm. In any instance, the polysilicon gate electrode 238 desirably has a thickness ranging from about 50 nm to about 150 nm.

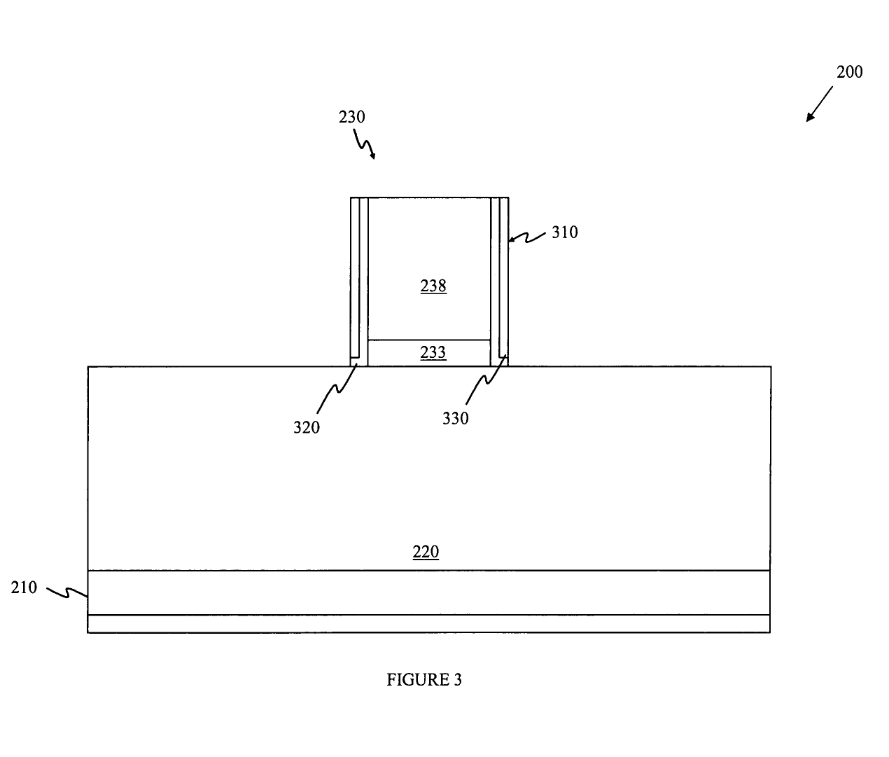

Turning briefly to FIG. 3 illustrated is a cross-sectional view of the partially completed semiconductor device 200 illustrated in FIG. 2 after formation of portions of gate sidewall spacers 310. The portions of the gate sidewall spacers 310 shown in FIG. 3 include an oxide layer 320 and an offset nitride spacer 330. The oxide layer 320, as compared to similar layers used in the prior art, may be formed at least partially using a deposition process. In an exemplary process the oxide layer 320 is initially formed using a first deposition process, and then finished using a second oxidation process. The first deposition process allows the oxide layer 320 to form on the top and sidewalls of the gate structure 230 when they do not comprise silicon. In an alternative embodiment the entire oxide layer 320 is either grown or deposited.

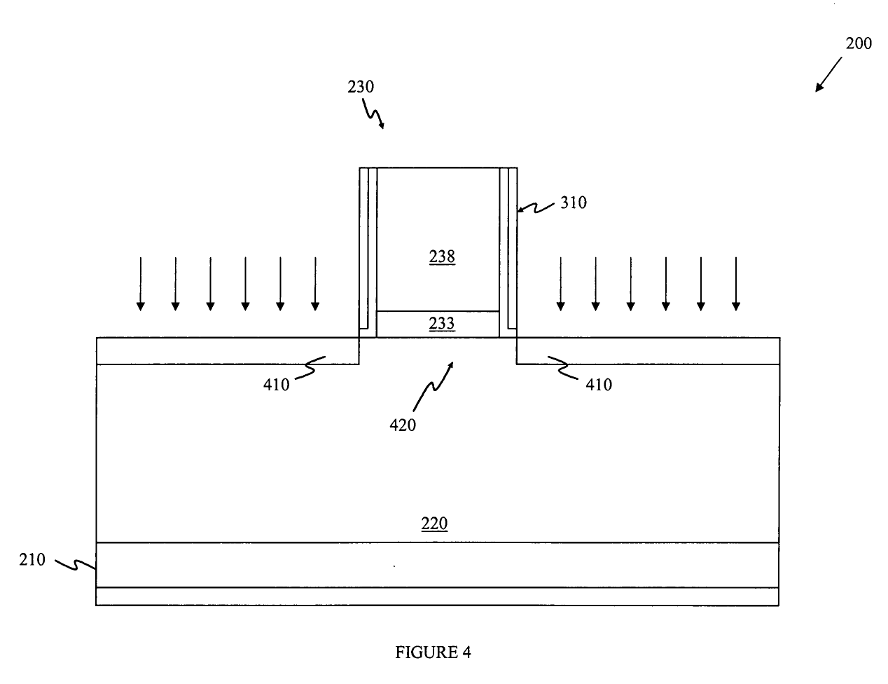

The offset nitride spacer 330 may comprise a standard silicon nitride spacer or a silicon nitride layer having carbon therein. If the offset nitride spacer 330 were to contain the carbon, the carbon might form from about 5% to about 10% of the layer. While the oxide layer 320 and the offset nitride spacer 330 are shown located only along the sides of the gate structure 230, those skilled in the art are aware that the layers were previously blanket formed and subsequently anisotropically etched to form the oxide layer 320 and the offset nitride spacer 330. It should be noted that certain embodiments may exist where the blanket oxide layer 320 and blanket nitride layer 330 would remain at this point and not be anisotropically etched as shown in FIG. 3. One skilled in the art understands that the embodiment of FIG. 3 is just an exemplary embodiment and that the oxide layer 320 and the offset nitride spacer 330 could easily be formed after the lightly doped source/drain extension implants 410 (FIG. 4).

Turning now to FIG. 4, illustrated is a cross-sectional view of the partially completed semiconductor device 200 illustrated in FIG. 3 after formation of lightly doped source/drain extension implants 410 within the substrate 210. The lightly doped source/drain extension implants 410 are conventionally formed and generally have a peak dopant concentration ranging from about 1E19 atoms/cm³ to about 2E20 atoms/cm³. As is standard in the industry, the lightly doped source/drain extension implants 410 have a dopant type opposite to that of the well region 220 they are located within. Accordingly, the lightly doped source/drain extension implants 410 are doped with an N-type dopant in the illustrative embodiment shown in FIG. 4, and form a channel region 420.

Anytime after forming at least a portion of the source/drain regions, which in the embodiment illustrated in FIG. 4 happens to be soon after forming the lightly doped source/drain extension implants 410, the semiconductor device 200 may be annealed in the presence of hydrogen. As previously mentioned, the anneal in the presence of hydrogen allows the hydrogen to diffuse into the channel region 420 and advantageously permit any piled-up dopants, in this instance boron, to redistribute and/or diffuse out of the channel region 420. The lack of piled-up dopants in the channel region 420, therefore, improves channel mobility for electrons and/or holes through the channel region.

As those skilled in the art would expect, the annealing of the channel region 420 of the substrate 210 in the presence of hydrogen may be achieved using a number of different techniques. First, and possibly most common, the channel region 420 of the substrate 210 could be annealed in the presence of a hydrogen containing gas. For instance, the anneal could be conducted for a short period of time at a temperature ranging from about 850° C. to about 1150° C. in the presence of ammonia or a forming gas. In an alternative embodiment, a spike anneal up to a temperature of about 1150° C. in the presence of a hydrogen containing gas would work equally as well. Nevertheless, other times, temperatures and hydrogen containing gases could be used.

In a significantly different embodiment, the channel region 420 of the substrate 210 could be annealed in the presence of hydrogen in various chemical states, such as radicals or a hydrogen ions. Hydrogen radicals can be generated by energetic excitations such as laser illumination, and hydrogen plasma with positive and negative ions can be generated using a radio frequency generator. Other embodiments may nonetheless exist for generating hydrogen radicals or hydrogen ions.

While the discussion of annealing the channel region 420 of the substrate 210 in the presence of hydrogen has occurred soon after the formation of the lightly doped source/drain extension implants in the disclosed embodiment of the present invention, it may, in theory, be conducted any time after formation of any portion of the source/drain regions up and until forming the interlevel dielectric layer. For this reason, further references to the annealing of the semiconductor device 200 in the presence of hydrogen will be discussed with respect to other FIGUREs.

It should additionally be noted that in instances where PMOS devices are located proximate the semiconductor device 200 during the anneal in the presence of hydrogen, an oxynitride film could be located over the lightly doped source/drain extension implants of the PMOS devices to avoid dopant loss, particularly boron loss, therefrom. In many instances the oxynitride film is already located over the surface of the substrate 210, including the substrate of the PMOS devices, and thus does not amount to an additional processing step.

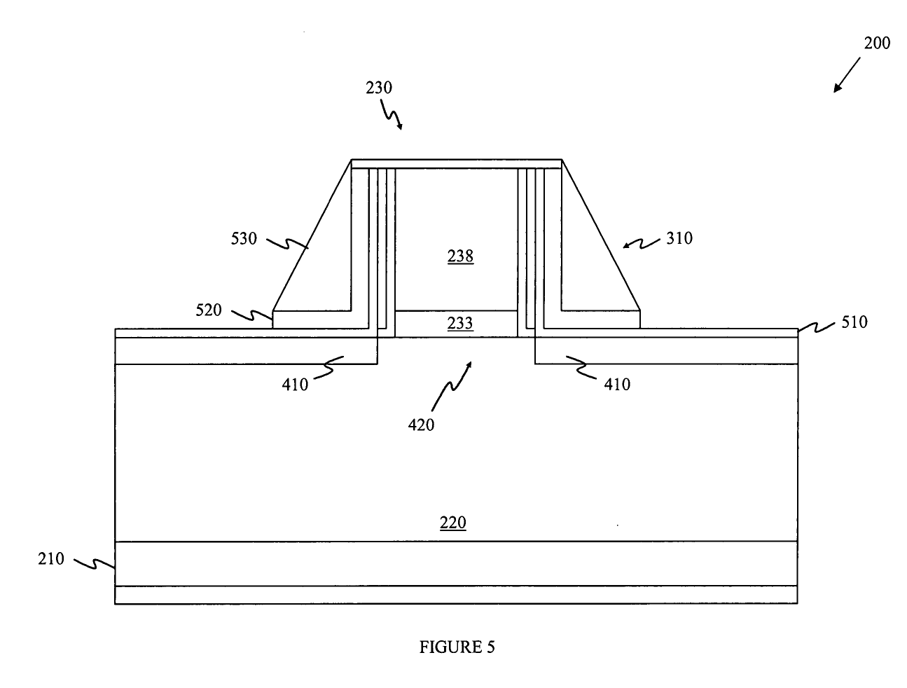

Turning now to FIG. 5, illustrated is a cross-sectional view of the partially completed semiconductor device 200 illustrated in FIG. 4, after annealing the semiconductor device 200 in the presence of hydrogen as referenced with respect to FIG. 4, and after forming additional portions of the gate sidewall spacers 310. Particularly, a cap oxide 510, L-shaped nitride spacers 520 and sidewall oxides 530 complete the gate sidewall spacers 310. The cap oxide 510, among other purposes, has the job of preventing the L-shaped nitride spacers 520 from directly contacting the substrate 210. Most likely, the cap oxide 510 will be deposited over the partially completed semiconductor device 200 using a process similar to that used to form the oxide layer 320. In an alternative embodiment, not shown, the cap oxide 510 is removed from a region above the lightly doped source/drain extension implants 410.

The L-shaped nitride spacers 520 may comprise any type of nitride, however, in an exemplary embodiment the L-shaped nitride spacers 520 comprise a nitride material that includes carbon. The carbon content, which may range from about 5% to about 10% of the L-shaped nitride spacers 520, is included within the L-shaped nitride spacers 520 to change the rate at which they etch. In the embodiment where the L-shaped nitride spacers 520 include carbon, the L-shaped nitride spacers 520 may be deposited using bis t-butylaminosilane (BTBAS) and ammonia (NH₃) precursors in a CVD reactor. Advantageously, the carbon causes the L-shaped nitride spacers 520 to etch at a slower rate than a traditional nitride layer. In an exemplary situation, after having been annealed using a temperature ranging from about 1000° C. to about 1100° C., the carbon causes the L-shaped nitride spacers 520 to have an etch selectivity of about 50:1 when compared to the traditional nitride layer.

The sidewall oxides 530 that are located over the L-shaped nitride spacers 520 are conventional. In the given embodiment of FIG. 5, the sidewall oxides 530 were blanket deposited and then subjected to an anisotropic etch. The resulting sidewall oxides 530 complete the gate sidewall spacers 310 illustrated in the embodiment of FIG. 5.

A substantial amount of detail has been given regarding the specifics of the gate sidewall spacers 310. Such should not be construed to be limiting on the present invention. For example, certain embodiments exist where only the offset spacer 330 and sidewall oxides 530, or another similar structure, comprise the gate sidewall spacers 310. Other embodiments exist where all the layers shown in FIG. 5 exist, however, the materials and thicknesses are different. In another embodiment of the invention, the material chosen for the gate sidewall spacers 310 is based on its disposable nature. Therefore, as previously noted, the detail given with respect to FIGS. 3 and 5 regarding the gate sidewall spacers should not be used to limit the scope of the present invention.

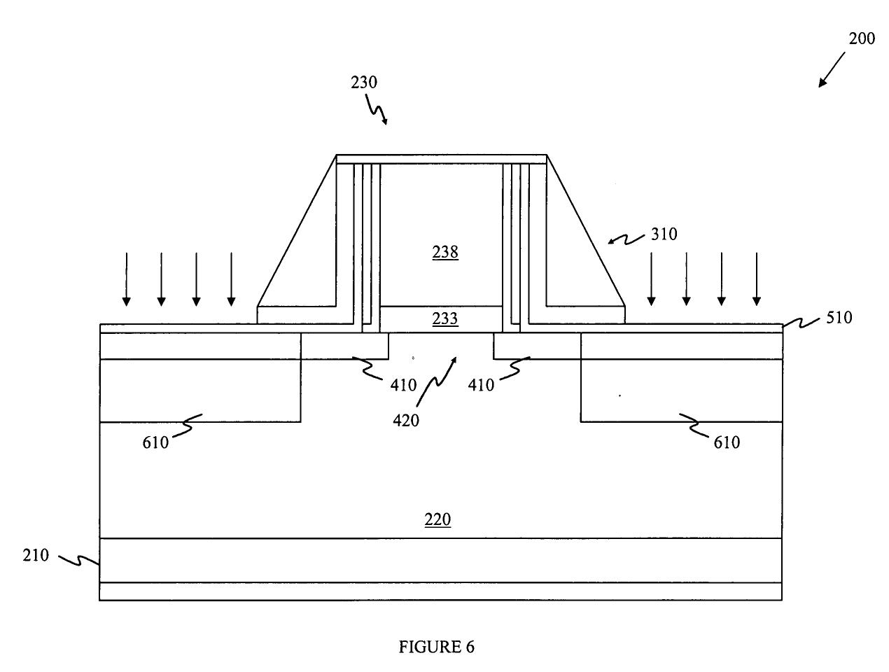

Turning now to FIG. 6, illustrated is a cross-sectional view of the partially completed semiconductor device 200 illustrated in FIG. 5 after the formation of highly doped source/drain implants 610 within the substrate 210. Those skilled in the art understand the conventional processes that could be used to form the highly doped source/drain implants 610. Generally the highly doped source/drain implants 610 have a peak dopant concentration ranging from about 1E18 atoms/cm³ to about 1E21 atoms/cm³. Also, the highly doped source/drain implants 610 should typically have a dopant type opposite to that of the well region 220 they are located within. Accordingly, in the illustrative embodiment shown in FIG. 6, the highly doped source/drain implants 610 are doped with an N-type dopant.

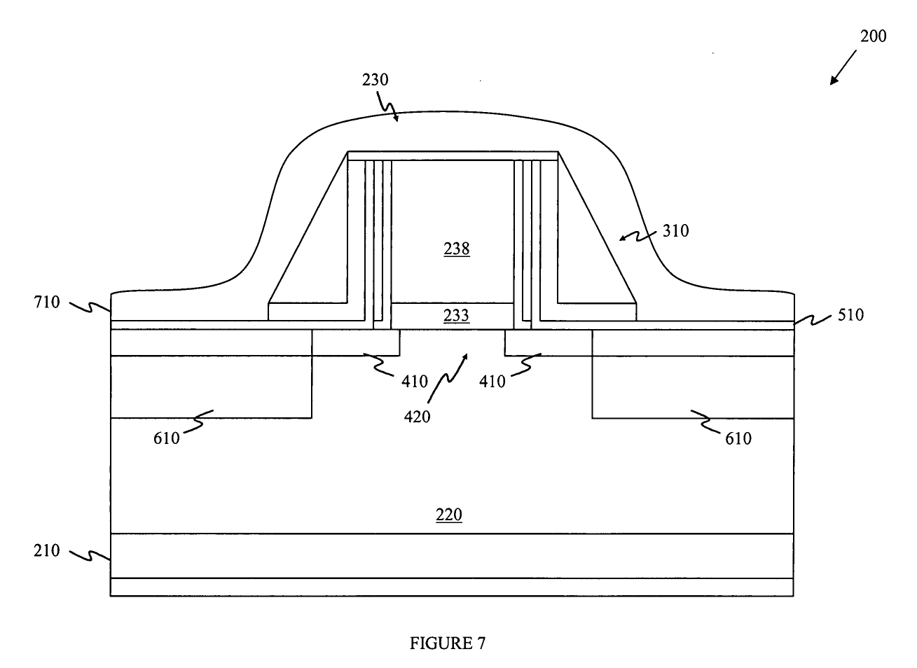

Turning now to FIG. 7, illustrated is a cross-sectional view of the partially completed semiconductor device 200 illustrated in FIG. 6 after forming a composite cap 710 over the substrate 210 in accordance with the principles of the present invention. In one exemplary embodiment of the invention the composite cap 710 is a nitride composite cap. The composite cap 710 is typically deposited by a low temperature chemical vapor deposition process. However, it is appreciated that other suitable processes can be employed to form/deposit the composite cap 710.

The composite cap 710 may further comprise a relatively thin liner (not shown), typically comprised of oxide or oxynitride, and a nitride layer formed/deposited on the thin liner. An example of a suitable thickness for the thin liner is about 5 nm to about 10 nm and an example of a suitable thickness for the nitride layer is about 80 nm or more. It is noted that the composite cap 710 can be selectively removed from portions of the semiconductor device 200 so as to not cover PMOS devices through an additional patterning step followed by combinations of wet and/or plasma etch. The benefits of this selective depositing are related to the deleterious effects of the composite cap 710 on PMOS devices.

After forming the composite cap 710, the semiconductor device 200 may be subjected to a rapid thermal anneal process in accordance with an aspect of the present invention. The rapid thermal anneal process is a rapid heating procedure that is typically performed at about 1000° C. to about 1100° C. for less than about 5 seconds. The purpose of the anneal is to activate the dopants implanted for the lightly doped source/drain extension implants 410 and heavily doped source/drain implants 610, and to cure crystal damage induced by the previous active implant process. The thermal activation can, in certain embodiments, be performed in pure nitrogen or hydrogen containing gases.

In certain embodiments, the composite cap 710 has an abundance of hydrogen therein that can reach as high as about>20′ depending on the deposition conditions. During the rapid thermal anneal, hydrogen may be released from the composite cap 710 and is introduced into the surrounding structures, such as the sidewall oxide and the thin liner under the nitride. Because of the increased hydrogen concentration in the oxide from the hydrogen in the composite cap 710, p-type dopant (e.g., boron) segregation from the channel region 420 to the cap oxide 510 and/or the composite cap 710 is enhanced. As a result, there is a net boron dopant loss in the channel region 420, which reduces the dopant pile-up at the Si/SiO² interface. Therefore, the hydrogen further modifies the dopant profile for the channel region 420 and further creates a retrograde profile (lower concentration of p dopant near the surface and/or channel/gate oxide interface), and improves the electron mobility for the channel region 420. Because the impact on the dopant profile is directly caused by the hydrogen diffusion, it is observed that the higher the concentration of hydrogen in the composite cap 710, the more improvement is achieved for the NMOS transistors. Therefore, a CVD silicon nitride film is generally a better choice for the composite cap 710 than a CVD silicon oxide, because typically the former contains more hydrogen than the latter. Also, deposition condition can greatly change the hydrogen concentration in the film. For example, the hydrogen concentration greatly increases as the deposition temperature decreases. It should also be pointed out that any suitable composite cap 710 material may be used. For example, any film containing a high concentration of hydrogen that is releasable upon annealing can work for this purpose.

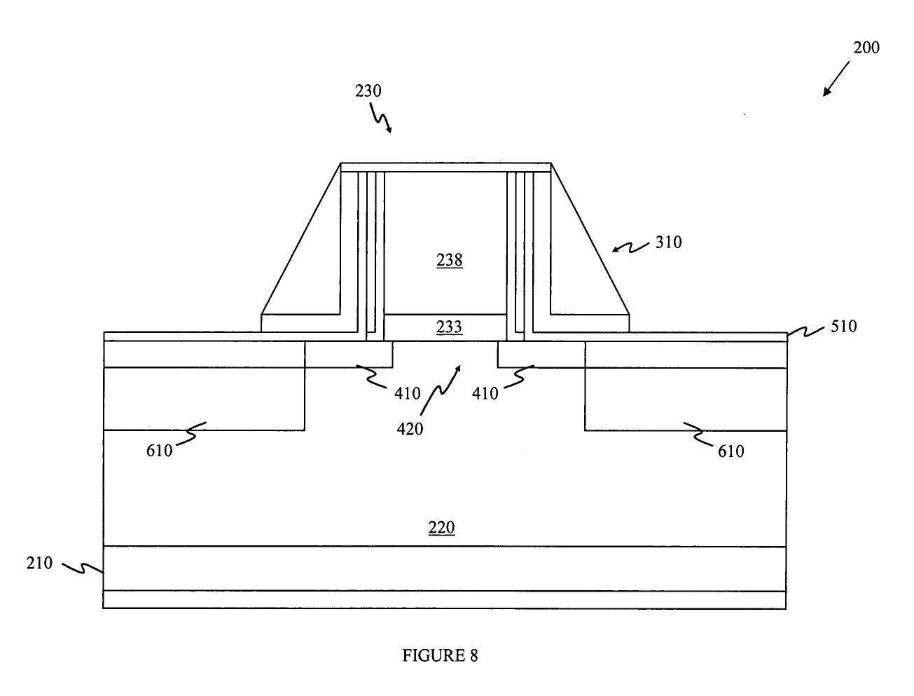

Turning now to FIG. 8, illustrated is a cross-sectional view of the partially completed semiconductor device 200 illustrated in FIG. 7 after removing the composite cap 710. In the embodiment of FIG. 8 the composite cap 710 has been removed using a blanket wet etch, although other suitable etching mechanisms can be employed. At this point of fabrication (after the anneal and the composite cap removal), the channel mobility for the channel region 410 has been improved due to the retrograde profile.

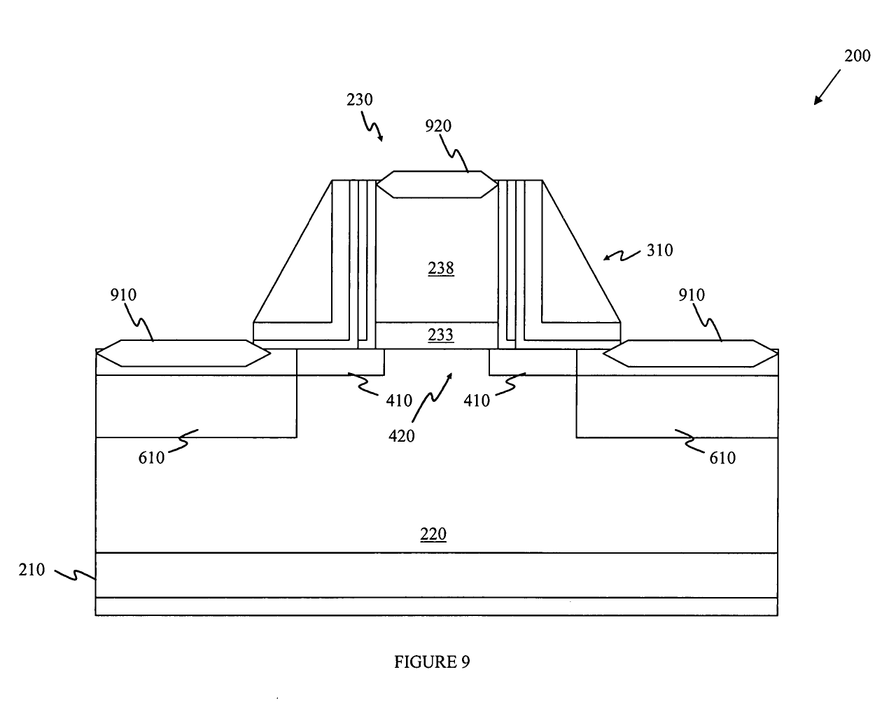

Turning now to FIG. 9, illustrated is a cross-sectional view of the partially completed semiconductor device 200 illustrated in FIG. 8 after conventionally forming silicided source/drain regions 910 and a silicided gate electrode layer 920. The skilled artisan understands the conventional silicided source/drain region 910 and silicided gate electrode layer 920 formation process. In sum, the process includes forming a metal layer, possibly cobalt, nickel, etc., over the substrate 210 and gate structure 230, and subjecting the metal layer to an anneal, causing the metal to react with the silicon of the substrate 210, and in this instance the gate electrode layer 238, and form the silicided source/drain regions 910 and silicided gate electrode layer 920.

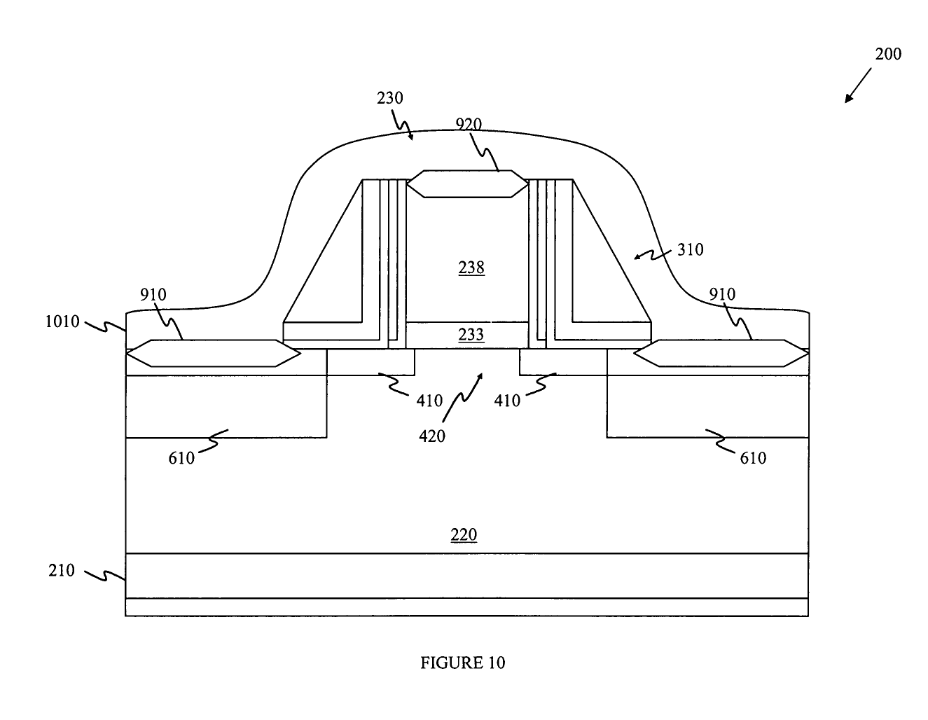

Turning now to FIG. 10, illustrated is a cross-sectional view of the partially completed semiconductor device 200 illustrated in FIG. 9 after forming a stress-inducing layer 1010, such as a PMD liner, over the gate structure 230 and substrate 210. The stress-inducing layer 1010, which in the embodiment of FIG. 10 happens to be a nitride layer, is typically deposited by a low temperature plasma enhanced chemical vapor deposition (PECVD) process. However, it is appreciated that other suitable processes can be employed to form/deposit the stress-inducing layer 1010.

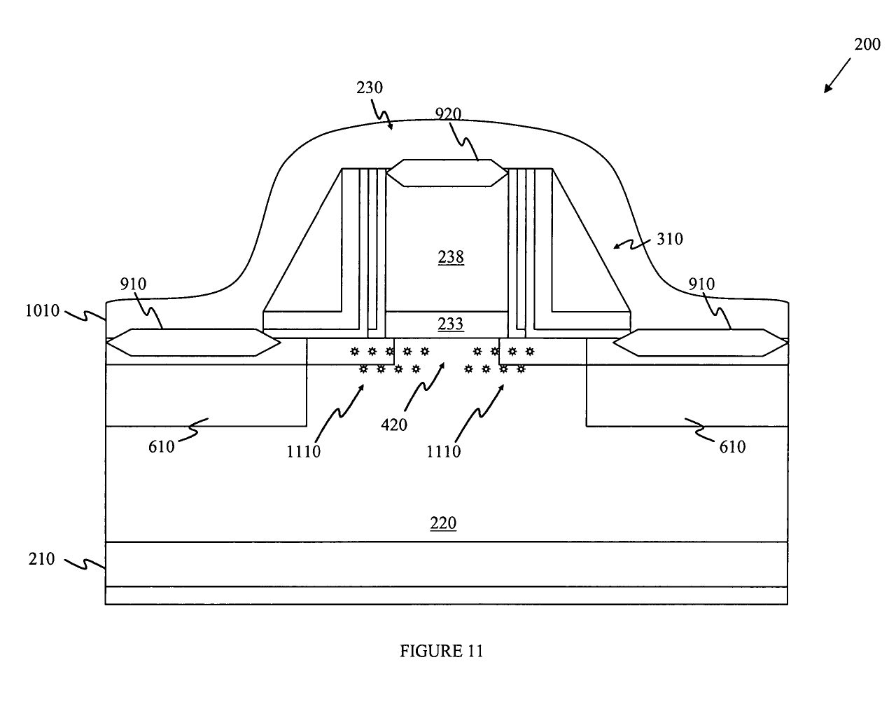

Turning now to FIG. 11, illustrated is a cross-sectional view of the partially completed semiconductor device 200 illustrated in FIG. 10 after subjecting the stress-inducing layer 1010 to a thermal anneal to impart a stress 1110 into a channel region 420 under the gate structure 230. The thermal anneal, which happens to be a rapid thermal anneal in the exemplary embodiment of FIG. 11, is typically performed at a temperature of greater than about 350° C., and less than about 800° C., for a time period of less than about 180 seconds. The selection of the anneal temperature should be compatible with the chosen silicide material, to avoid degradation in silicide conductivity.

In another exemplary embodiment of the invention the thermal anneal of the stress-inducing layer 1010 is conducted in the presence of hydrogen or a hydrogen containing gas. Similar to the anneal in the presence of hydrogen discussed with respect to FIG. 4, the anneal in the presence of hydrogen benefits the semiconductor device 200. When the semiconductor device 200 is annealed in the presence of hydrogen at the stage discussed with respect to FIG. 11, the hydrogen appears to improve the interface state properties of the semiconductor device 200. Additionally, this hydrogen appears to improve the negative bias temperature instability (NBTI) properties of PMOS devices.

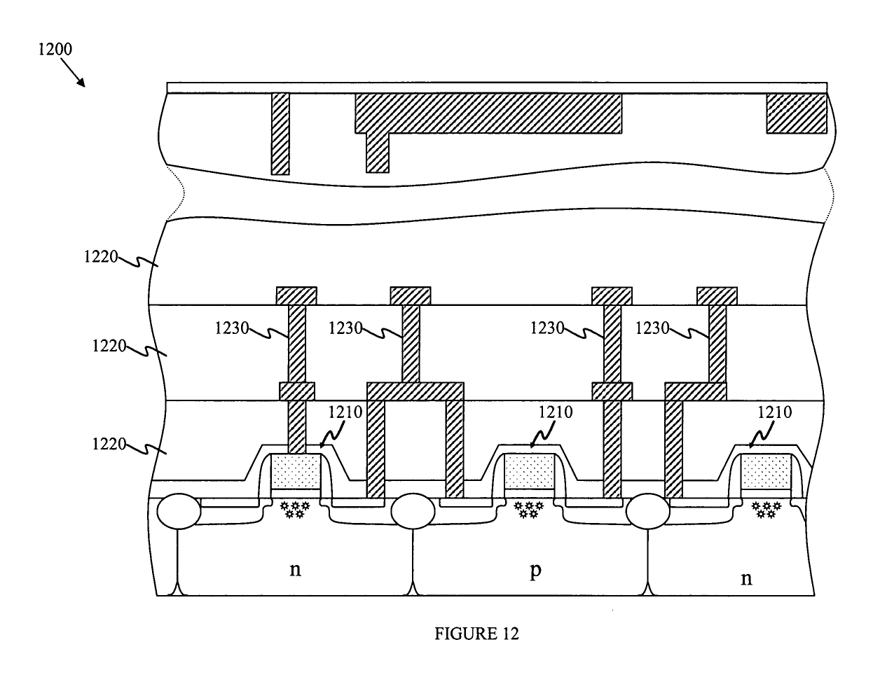

Referring finally to FIG. 12, illustrated is a cross-sectional view of a conventional integrated circuit (IC) 1200 incorporating a semiconductor device 1210 constructed according to the principles of the present invention. The IC 1200 may include devices, such as transistors used to form CMOS devices, BiCMOS devices, Bipolar devices, or other types of devices. The IC 1200 may further include passive devices, such as inductors or resistors, or it may also include optical devices or optoelectronic devices. Those skilled in the art are familiar with these various types of devices and their manufacture. In the particular embodiment illustrated in FIG. 12, the IC 1200 includes semiconductor devices 1210 having dielectric layers 1220 located thereover. Additionally, interconnect structures 1230 are located within the dielectric layers 1220 to interconnect various devices, thus, forming the operational integrated circuit 1200.

Although the present invention has been described in detail, those skilled in the art should understand that they can make various changes, substitutions and alterations herein without departing from the spirit and scope of the invention in its broadest form.

1. A method for manufacturing a semiconductor device, comprising:
forming a gate structure over a substrate;
forming at least a portion of source/drain regions in the substrate;
annealing the substrate containing the at least a portion of source/drain regions in the presence of hydrogen; and
forming an interlevel dielectric layer over the substrate having previously been annealed in the presence of hydrogen.

2. The method as recited in claim 1 wherein forming at least a portion of source/drain regions includes forming lightly doped source/drain extension implants, and wherein annealing the substrate occurs after forming the lightly doped source/drain extension implants and before forming highly doped source/drain implants.

3. The method as recited in claim 1 further including forming a PMD liner over the gate structure and substrate after a formation of silicide regions in completed source/drain regions, and then annealing the substrate containing the completed source/drain regions in the presence of hydrogen.

4. The method as recited in claim 1 wherein annealing the substrate in the presence of hydrogen includes annealing the substrate in the presence of a hydrogen containing gas.

5. The method as recited in claim 4 wherein the hydrogen containing gas is ammonia or a forming gas.

6. The method as recited in claim 1 wherein annealing the substrate in the presence of hydrogen includes annealing the substrate in the presence of a hydrogen radical or hydrogen plasma.

7. The method as recited in claim 1 wherein annealing the substrate in the presence of hydrogen includes annealing at a temperature ranging from about 350° C. to about 1150° C.

8. The method as recited in claim 7 wherein annealing the substrate in the presence of hydrogen includes spike annealing the substrate in the presence of hydrogen.

9. The method as recited in claim 1, further including forming a composite cap over the substrate after annealing the substrate in the presence of hydrogen, the composite cap providing an additional source of hydrogen to the substrate.

10. The method as recited in claim 1 wherein the semiconductor device is an NMOS device and the annealing in the presence of hydrogen substantially reduces boron pileup at an interface between the gate structure and the substrate.

11. A method for manufacturing an integrated circuit, comprising:
forming semiconductor devices over a substrate, including;
forming a gate structure over the substrate;
forming at least a portion of source/drain regions in the substrate; and
annealing the substrate containing the at least a portion of source/drain regions in the presence of hydrogen;
forming an interlevel dielectric layer over the substrate having previously been annealed in the presence of hydrogen; and
forming interconnects within the interlevel dielectric layer and contacting the semiconductor devices thereby forming an operational integrated circuit.

12. The method as recited in claim 11 wherein forming at least a portion of source/drain regions includes forming lightly doped source/drain extension implants, and wherein annealing the substrate occurs after forming the lightly doped source/drain extension implants and before forming highly doped source/drain implants.

13. The method as recited in claim 11 further including forming a PMD liner over the gate structure and substrate after formation of silicide regions in completed source/drain regions, and then annealing the substrate containing the completed source/drain regions in the presence of hydrogen.

14. The method as recited in claim 11 wherein annealing the substrate in the presence of hydrogen includes annealing the substrate in the presence of a hydrogen containing gas.

15. The method as recited in claim 14 wherein the hydrogen containing gas is ammonia or a forming gas.

16. The method as recited in claim 11 wherein annealing the substrate in the presence of hydrogen includes annealing the substrate in the presence of a hydrogen radical or hydrogen plasma.

17. The method as recited in claim 11 wherein annealing the substrate in the presence of hydrogen includes annealing at a temperature ranging from about 350° C. to about 1150° C.

18. The method as recited in claim 17 wherein annealing the substrate in the presence of hydrogen includes spike annealing the substrate in the presence of hydrogen.

19. The method as recited in claim 11, further including forming a composite cap over the substrate after annealing the substrate in the presence of hydrogen, the composite cap providing an additional source of hydrogen to the substrate.

20. The method as recited in claim 11 wherein the semiconductor device is an NMOS device and the annealing in the presence of hydrogen substantially reduces boron pileup at an interface between the gate structure and the substrate.
